(19) United States
(12) Patent Application Publication
(10) Pub. No.: US 2025/0105589 A1
(43) Pub. Date: Mar. 27, 2025

(54) CONTINUOUS FREQUENCY-TUNING ARRAY LIGHT SOURCE

(71) Applicant: ELECTRONICS AND TELECOMMUNICATIONS RESEARCH INSTITUTE, Daejeon (KR)

(72) Inventors: Oh Kee KWON, Daejeon (KR); Chul-Wook LEE, Daejeon (KR)

(21) Appl. No.: 18/799,772

(22) Filed: Aug. 9, 2024

(30) Foreign Application Priority Data
Sep. 27, 2023 (KR) 10-2023-0130226

(51) Int. Cl. H01S 5/12; H01S 5/02; H01S 5/028; H01S 5/34

(52) U.S. Cl. CPC H01S 5/1237; H01S 5/0207; H01S 5/028; H01S 5/3401

(57) ABSTRACT

Provided is a continuous frequency-tuning array light source. The light source may include a substrate including a gain region, a phase modulation region, and an internal reflection region arranged in a first direction, a core layer extending in the first direction on the substrate and including a grating in the internal reflection region, an upper clad layer on the core layer and the substrate, external reflection coating on one side wall of the substrate adjacent to the gain region, the core layer, and the upper clad layer, a dielectric layer on the upper clad layer in the phase modulation region and the internal reflection region, an ohmic contact layer on the upper clad layer in the gain region, and electrodes on the dielectric layer and the ohmic contact layer.

### CROSS-REFERENCE TO RELATED APPLICATIONS

This U.S. non-provisional patent application claims priority under 35 U.S.C. §119 of Korean Patent Application No. 10-2023-0130226, filed on Sep. 27, 2023, the entire contents of which are hereby incorporated by reference.

### BACKGROUND

Nowadays, a continuous frequency-tuning laser diode is required to implement a frequency-swept source of optical coherent tomography (OCT), automatic optical inspection (AOI), or light detection and range (LiDAR). Although there is a difference in required performance according to an application target and manner, it is also required to develop a light source having high power for large-area image detection, a narrow linewidth for long coherent length, or a wide frequency-tuning range for precise distance resolution.

### SUMMARY

The present disclosure provides a continuous frequency-tuning array light source that may continuously tune frequencies of laser light without mode hopping and increase the tuning efficiency.

An embodiment of the inventive concept provides a continuous frequency-tuning array light source including: a substrate including a gain region, a phase modulation region, and an internal reflection region arranged in a first direction; a core layer extending in the first direction on the substrate and including a grating in the internal reflection region; an upper clad layer on the core layer and the substrate; external reflection coating on one side wall of the substrate adjacent to the gain region, the core layer, and the upper clad layer; a dielectric layer on the upper clad layer in the phase modulation region and the internal reflection region; an ohmic contact layer on the upper clad layer in the gain region; and electrodes on the dielectric layer and the ohmic contact layer.

In an embodiment, the substrate may include air holes in the phase modulation region and the internal reflection region.

In an embodiment, the air holes may include: first air holes provided in the phase modulation region and having a first thickness; and second air holes provided in the internal reflection region and having a second thickness smaller than the first thickness.

In an embodiment, the core layer may have a third thickness in the gain region and the internal reflection region, and a fourth thickness greater than the third thickness in the phase modulation region.

In an embodiment, the core layer may have a first width in the phase modulation region, and a second width greater than the first width in the internal reflection region.

In an embodiment, the upper clad layer may have has a fifth thickness in the gain region and a sixth thickness smaller than the fifth thickness in the phase modulation region.

In an embodiment, the upper clad layer may haves a seventh thickness smaller than the fifth thickness and greater than the sixth thickness in the internal reflection region.

In an embodiment, the gain region may gave a first length and the phase modulation region may have a second length smaller than the first length.

In an embodiment, the continuous frequency-tuning array light source may further include a bottom electrode provided under the substrate.

In an embodiment, the core layer may include a quantum well layer in the gain region.

In an embodiment of the inventive concept, a continuous frequency-tuning array light source includes: a substrate having a gain region, a phase modulation region, an internal reflection region, an amplification region, and a coupling region arranged in a first direction and having air holes in the phase modulation region and the internal reflection region; a core layer provided on the substrate, extending from the gain region to the coupling region, having a grating in the internal reflection region, and being selectively thick in the phase modulation region; an upper clad layer disposed on the core layer and the substrate, and being selectively thin in the phase modulation region; external reflection coating on one side wall of the substrate, the core layer, and the upper clad layer of the gain region; anti-reflection coating disposed on another side wall of the substrate, the core layer, and the upper clad layer; a dielectric layer on the upper clad layer in the phase modulation region and the internal reflection region; an ohmic contact layer on the upper clad layer in the gain region; and electrodes on the dielectric layer and the ohmic contact layer.

In an embodiment, the air holes may include: first air holes provided in the phase modulation region and having a first thickness; and second air holes provided in the internal reflection region and having a second thickness smaller than the first thickness.

In an embodiment, the core layer may have a third thickness in the gain region and the internal reflection region, and a fourth thickness greater than the third thickness in the phase modulation region.

In an embodiment, the core layer may have a first width in the phase modulation region, and a second width greater than the first width in the internal reflection region.

In an embodiment, the upper clad layer may have a fifth thickness in the gain region and a sixth thickness smaller than the fifth thickness in the phase modulation region, and the upper clad layer may have a seventh thickness smaller than the fifth thickness and greater than the sixth thickness in the internal reflection region.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is an example continuous frequency-tuning array light source according to the present inventive concept;

FIG. 2 is a cross-sectional view cut and viewed on line I-I′ of FIG. 1;

FIG. 3 shows a graph of wavelength variation range versus fourth thickness of the passive core layer within the phase modulation region of FIG. 2;

FIG. 4 shows a graph of wavelength change ratio versus fourth thickness of the passive core layer within the phase modulation region of FIG. 2;

FIG. 5 is a plan view showing an example of the clad layer of FIG. 2;

FIG. 6 shows a graph of wavelength variation range versus first thickness of the core layer in the phase modulation region of FIG. 5;

FIG. 7 shows a graph of wavelength change ratio versus first thickness of the core layer in the phase modulation region of FIG. 5;

FIG. 8 shows a graph of wavelength variation range versus sixth thickness of the upper clad layer within the phase modulation region of FIG. 2;

FIG. 9 shows a graph of wavelength change ratio versus sixth thickness of the upper clad layer in the phase modulation region of FIG. 2;

FIG. 10 shows graphs of peak wavelength versus frequency of laser light generated in a continuous frequency-tuning array light source;

FIG. 11 shows a graph of wavelength variation range of laser light versus modulation current provided to the electrodes of the phase modulation region of FIG. 2;

FIG. 12 shows a graph of peak wavelength versus modulation current provided to the electrodes of the phase modulation region of FIG. 2;

FIG. 13 shows a graph of driving spectrum for each channel of the laser light generated in the continuous frequency-tuning array light sources of FIG. 1;

FIG. 14 is a plan view showing an example continuous frequency-tuning array light source according to the present inventive concept;

FIG. 15 is a plan view showing an example continuous frequency-tuning array light source according to the present inventive concept; and

FIG. 16 is a plan view showing an example continuous frequency-tuning array light source according to the present inventive concept.

### DETAILED DESCRIPTION

Hereinafter, specific embodiments will be described in detail with reference to the accompanying drawings. Advantages and features of the present invention, and methods for achieving the same will be cleared with reference to exemplary embodiments described later in detail together with the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. The present disclosure is defined by only scopes of the claims. Throughout this specification, like numerals refer to like elements.

The terms and words used in the following description and claims are to describe embodiments but are not limited the inventive concept. As used herein, the singular forms “a”, “an” and “the” are intended to include the plural forms as well, unless the context clearly indicates otherwise. It will be further understood that the terms “comprises” and/or “comprising” used herein specify the presence of stated components, operations and/or elements but do not preclude the presence or addition of one or more other components, operations and/or elements. In addition, as just exemplary embodiments, reference numerals shown according to an order of description are not limited to the order.

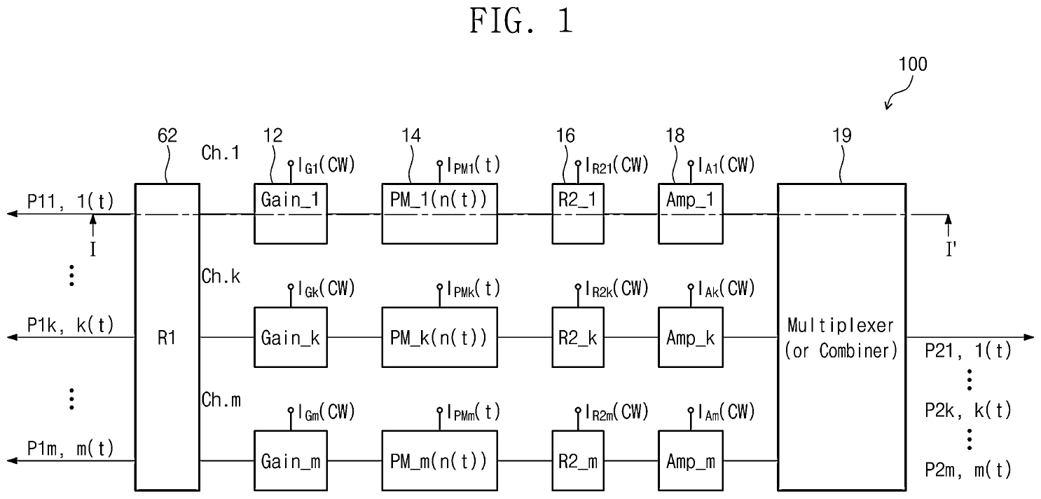

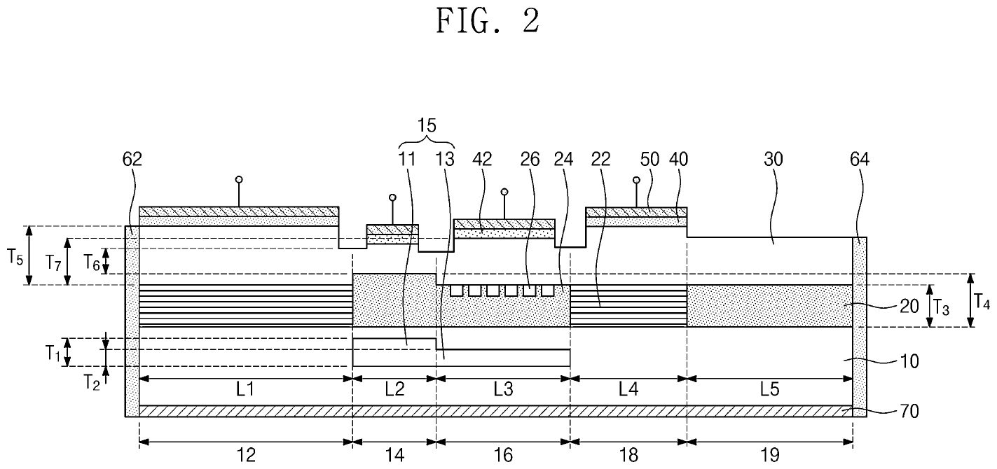

FIG. 1 is an example continuous frequency-tuning array light source 100 according to the present inventive concept. FIG. 2 is a cross section cut and viewed on line I-I′ of FIG. 1.

Referring to FIGS. 1 and 2, each continuous frequency-tuning array light source 100 may include a DBR-LD. According to an example, each continuous frequency-tuning array light source 100 may include a substrate 10, a core layer 20, an upper clad layer 30, an ohmic contact layer 40, a dielectric layer 42, electrodes 50, external reflection coating 62, anti-reflection coating 64, and a bottom electrode 70.

The substrate 10 may include n-type InP. The substrate 10 may be a lower clad layer, but is not limited thereto. According to an example, the substrate 10 may include a gain region 12, a phase modulation region 14, an internal reflection region 16, an amplification region 18, and a coupling region 19 that are arranged in a first direction. The gain region 12 may acquire the gain of laser light. The gain region 12 may be longer than each of the phase modulation region 14, the internal reflection region 16, and the amplification region 18. The gain region 12 may have a first length L1. The phase of the laser light may be modulated in the phase modulation region 14. The phase modulation region 14 may have a second length L2 shorter than the first length L1. The laser light may be reflected by the internal reflection area 16 to the external reflection coating 62. The phase modulation region 16 may have a third length L3 shorter than the first length L1 and longer than the second length L2. The output power of the laser light may increase in the gain region 12 of the first length L1 greater than the second length L2 or the third length L3. The speed of a frequency-tuning operation may increase in the phase modulation region 14 shorter than the internal reflection region 16 or the gain region 12. The internal reflection coating 62, the gain region 12, the phase modulation region 14, and the internal reflection region 16 may serve as a resonator or a resonance region.

According to an example, the substrate 10 may have air holes 15 in the phase modulation region 14 and the internal reflection region 16. The air holes 15 may increase a heat constraint of the electrodes 50 to increase or improve a frequency-tuning efficiency of laser light. The air holes 15 may include a first air hole 11 and a second air hole 13. The first air hole 11 may be provided in the phase modulation region 14. The first air hole 11 may be thicker or higher than the second hole 13. The first air hole 11 may increase a modulation efficiency and frequency-tuning efficiency of the laser light in the phase modulation region 14. The first air hole 11 may have a first thickness T₁. The second air hole 13 may be provided in the internal reflection region 16. The second air hole 13 may have a second thickness T₂ smaller than the first thickness T₁.

The intensity of the laser light may be amplified in the amplification region 18. The amplification region 18 may have a fourth length L4 smaller than the first length L1 or the third length L3, and greater than the second length L2.

Referring to FIG. 1, the respective numbers of the gain regions 12, the phase modulation regions 14, the internal reflection regions 16, and the amplification regions 18 connected in an array type may be 1 to m. The gain region 12, the phase modulation region 14, the internal reflection region 16, and the amplification region 18 may respectively receive currents of I_{Gk}(CW), I_{PMk}(t), I_{R2k}(CW), and I_{Ak}(CW) to resonate the laser light. Here, CW may denote a continuous wave, k may be an integer value of 1 to m, and t denotes a time. n(t) may denote a refractive index of a time-dependent optical path, P1k and P2k denote the power of the laser light traveling from the gain region 12 to the coupling region 19, and νk(t) may denote a time(t)-dependent frequency of the laser light and change depending on I_{PMk}(t).

Channels of the gain regions 12, the phase modulation regions 14, internal reflection regions 16, and the amplification regions 16 are connected in the coupling region 19 to output the laser light. The coupling region 19 may have a fifth length L5 shorter than the first length L1 and longer than the third length L3. The coupling region 19 may serve as a multiplexer or a combiner.

Referring to FIG. 2, a core layer 20 may be provided on the substrate 10. The core layer 20 may extend from the gain region 12 to the coupling region in a first direction. The core layer 20 may have a higher refractive index than the substrate 10. The laser light may travel along the core layer 20. The core layer 20 may include an active core layer 22 and a passive core layer 24. The active core layer 22 may be provided in the gain region 12 and the amplification region 18. The active core layer 22 may have a quantum well structure. The passive core layer 24 may be provided in the phase modulation region 14, the internal reflection region 16, and the coupling region 19.

The passive core layer 24 may have a grating 26 in the internal reflection region 16. The grating 26 may be provided on the top surface of the passive core layer 24 in the internal reflection region. The grating 26 may reflect the laser light to the external reflection coating 62.

The passive core layer 24 may be selectively high or thick in the phase modulation region 14. The passive core layer 24 of the phase modulation region 14, which is thicker than the internal reflection region 16, may increase the heat efficiency and the frequency-tuning efficiency due to an increase in optical confinement factor. The passive core layer 24 may have a third thickness T₃ in the internal reflection region 16. In addition, the active core layer 22 may have the third thickness T₃. The passive core layer 24 may have a fourth thickness T₄ greater than the third thickness T₃ in the phase modulation region 14.

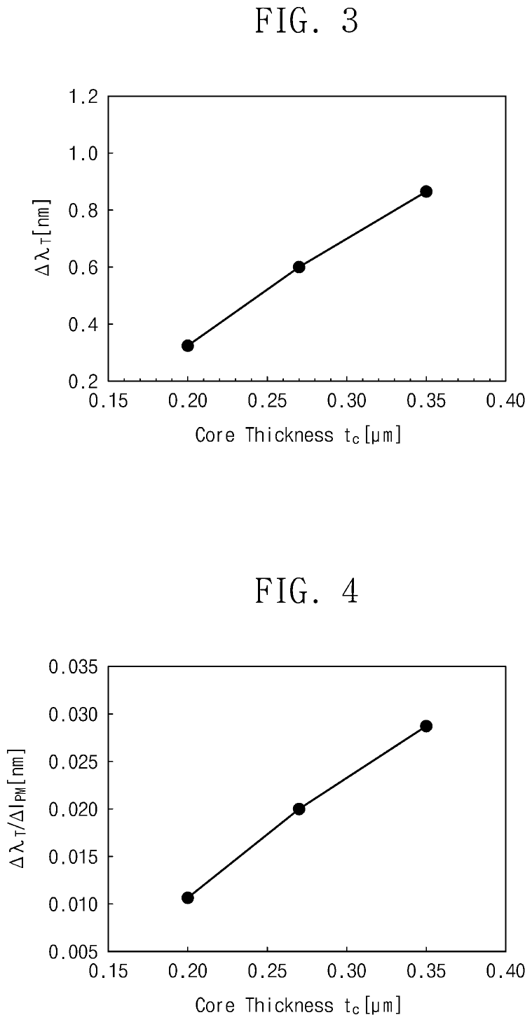

FIG. 3 shows a wavelength variation range according to the fourth thickness T₄ of the passive core layer 24 in the phase modulation region 14.

Referring to FIG. 3, as the fourth thickness T₄ of the passive core layer 24 become thicker, the wavelength variation range may increase.

FIG. 4 shows a wavelength change ratio according to the fourth thickness T₄ of the passive core layer 24 in the phase modulation region 14 of FIG. 2.

Referring to FIG. 4, as the fourth thickness T₄ of the passive core layer 24 increases, the wavelength change ratio may increase. When the fourth thickness T₄ is about 0.2 μm, the wavelength change ratio may be about 0.01 nm/mA. When the fourth thickness T₄ is about 0.27 μm, the wavelength change ratio may be about 0.02 nm/mA. When the fourth thickness T₄ is about 0.35 μm, the wavelength change ratio may be about 0.03 nm/mA. Here, the third thickness T₃ may be about 0.2 μm.

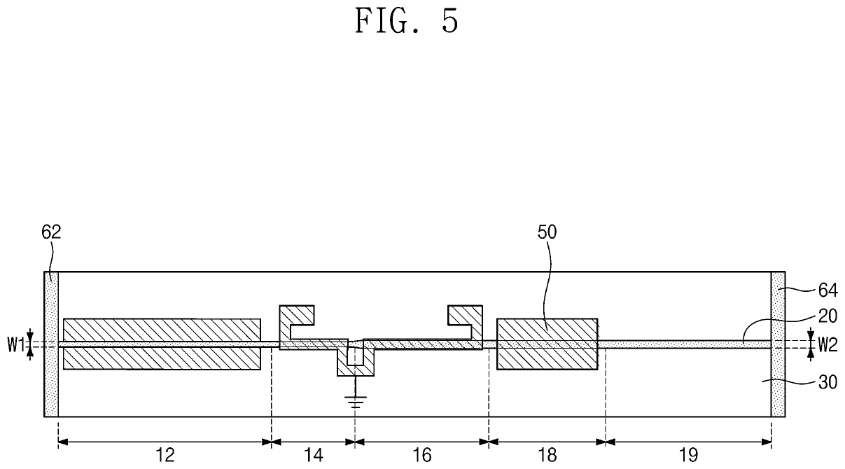

FIG. 5 shows an example of the core layer 20 of FIG. 2.

Referring to FIG. 5, the core layer 20 in the phase modulation region 14 may be selectively thin in comparison to that in the internal reflection region 16.

The core layer 20 may have a first width W1 in the phase modulation region 14. The core layer 20 may have a second width W2 greater than the first width W1 in the internal reflection region 16.

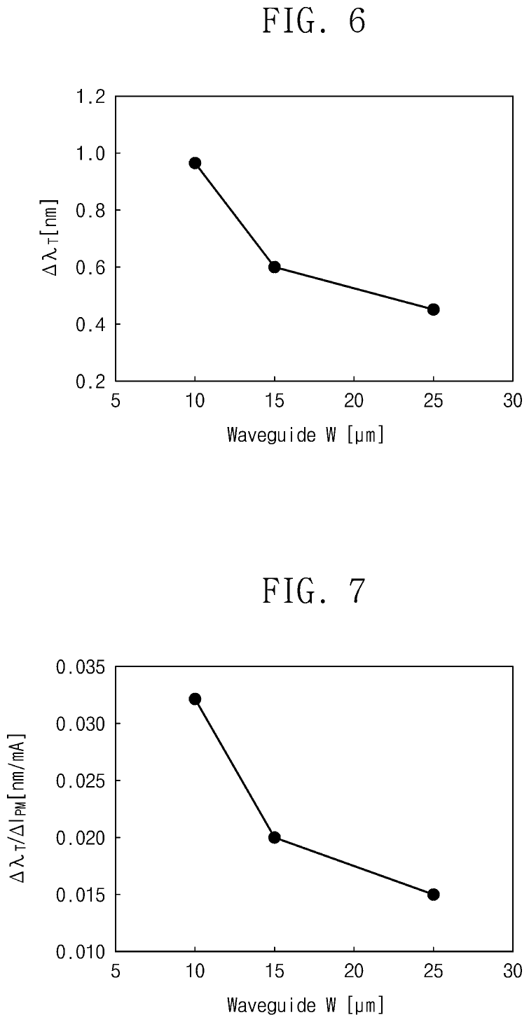

FIG. 6 shows a wavelength variation range according to the first width W1 of the core layer 20 in the phase modulation region 14 of FIG. 5.

Referring to FIG. 6, as the first width W1 of the core layer 20 decreases, the wavelength variation range may increase.

FIG. 7 shows a wavelength change ratio according to the first width W1 of the core layer 20 in the phase modulation region 14 of FIG. 5.

Referring to FIG. 7, as the first W1 of the core layer 20 decreases, the wavelength change ratio may increase. When the first width W1 is about 25 μm, the wavelength change ratio may be about 0.015 nm/mA. When the first width W1 is about 15 μm, the wavelength change ratio may be about 0.02 nm/mA. When the first W1 is about 10 μm, the wavelength change ratio may be about 0.032 nm/mA. Here, the second W2 may be about 25 μm.

Referring to FIG. 2, the upper clad layer 30 may be provided on the core layer 20. The upper clad layer 30 may include p-type InP. The upper clad layer 30 may be selectively thin in the phase modulation region 14.

The upper clad layer 30 may have a fifth thickness T₅ in the gain region 12 and the amplification region 18, a sixth thickness T₆ in the phase modulation region 14, and a seventh thickness T₇ in the internal reflection region 16. The fifth thickness T₅ may be greater than each of the sixth thickness T₆ and the seventh thickness T₇. The sixth thickness T₅ may be smaller than each of the fifth thickness T₅ and the seventh thickness T₇.

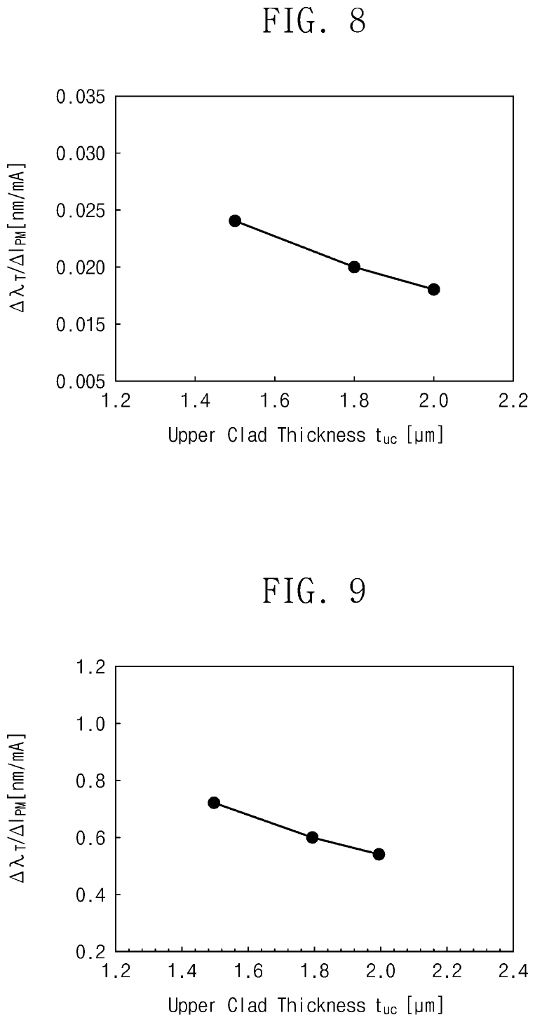

FIG. 8 shows a wavelength variation range according to the sixth thickness T₆ of the upper clad layer 30 in the phase modulation region 14 of FIG. 2.

Referring to FIG. 8, as the sixth thickness T₆ of the core layer 20 decreases, the wavelength variation range may increase.

FIG. 9 shows a wavelength change ratio according to the sixth T₆ of the upper clad layer 30 in the phase modulation region 14 of FIG. 2.

Referring to FIG. 9, as the sixth thickness T₆ of the core layer 20 in the phase modulation region 14 decreases, the wavelength change ratio may increase.

When the sixth thickness T₆ of the core layer 20 in the phase modulation region 14 is about 2 μm, the wavelength change ratio may be about 0.018 nm/mA. When the sixth thickness T₆ is about 1.8 μm, the wavelength change ratio may be about 0.02 nm/mA. When the sixth thickness T₆ is about 1.5 μm, the wavelength change ratio may be about 0.024 nm/mA.

Referring to FIG. 2, the anti-reflection coating 64 facing the external reflection coating 62 may be provided on the other side wall of the substrate 10, the core layer 20, and the upper clad layer 30. The anti-reflection coating 64 may output the laser light to the outside.

The ohmic contact layer 40 may be provided on the upper clad layer 30 of the gain region 12 and the amplification region 18. The ohmic contact layer 40 may include a metal or a metal dioxide.

The dielectric layer 42 may be provided on the upper clad layer 30 in the phase modulation region 14 and the internal reflection region 16. For example, the dielectric layer 42 may include silicon oxide or silicon nitride.

Referring to FIGS. 2 and 5, the electrodes 50 may be individually provided on the ohmic contact layer 40 and the dielectric layer 42 of the gain region 12, the phase modulation region 14, the internal reflection region 16, and the amplification region 18. The electrodes 50 may be used as heat electrodes in the phase modulation region 14 and the internal reflection region 16.

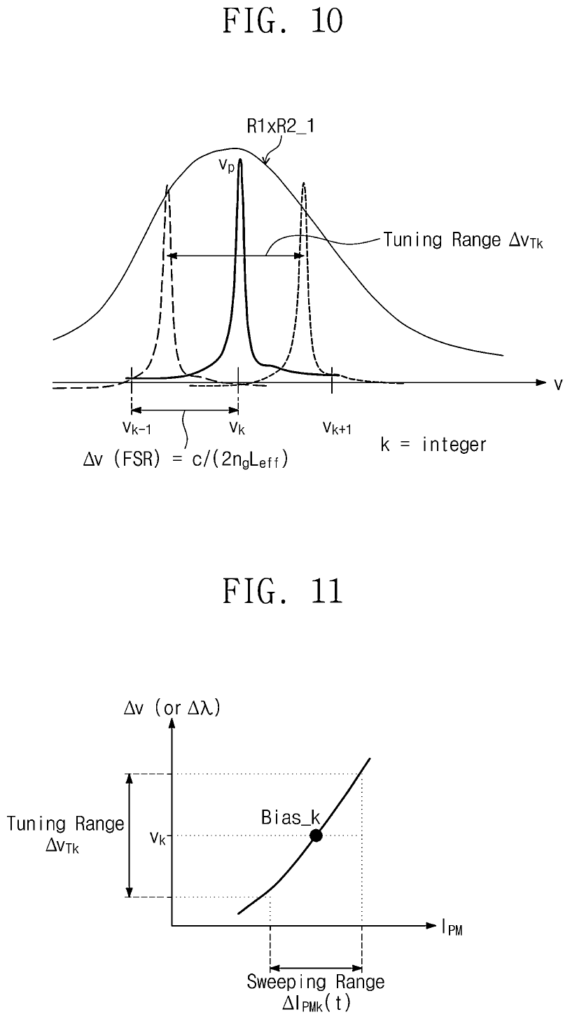

FIG. 10 shows a peak wavelength according to a frequency of the laser light generated in the continuous frequency-tuning array light source 100 of FIG. 1.

Referring to FIG. 10, a laser light spectrum may vibrate in one of cavity modes, and a free spectral range (FSR) Δν may be proportional to the light speed c and inversely proportional to a group refractive index n_{g} and an effective cavity length L_{eff}. The vibration modal frequency θₖ may be mainly determined by a vibration (phase) condition near a reflection spectrum peak value in the internal reflection region 16, and the phase may change in the phase modulation region 14 to tune the frequency. Here, νₚ denotes a peak frequency of vibration light, and the frequency-tuning range Δν_{Tk} may be tuned within a free spectral range Δν as long as there is not an additional tuning element in the cavity.

FIG. 11 shows the frequency-tuning range of the laser light according to a modulation current provided to the electrodes of the phase modulation region of FIG. 2.

Referring to FIG. 11, the tuning range of the laser light may increase in proportional to the modulation current.

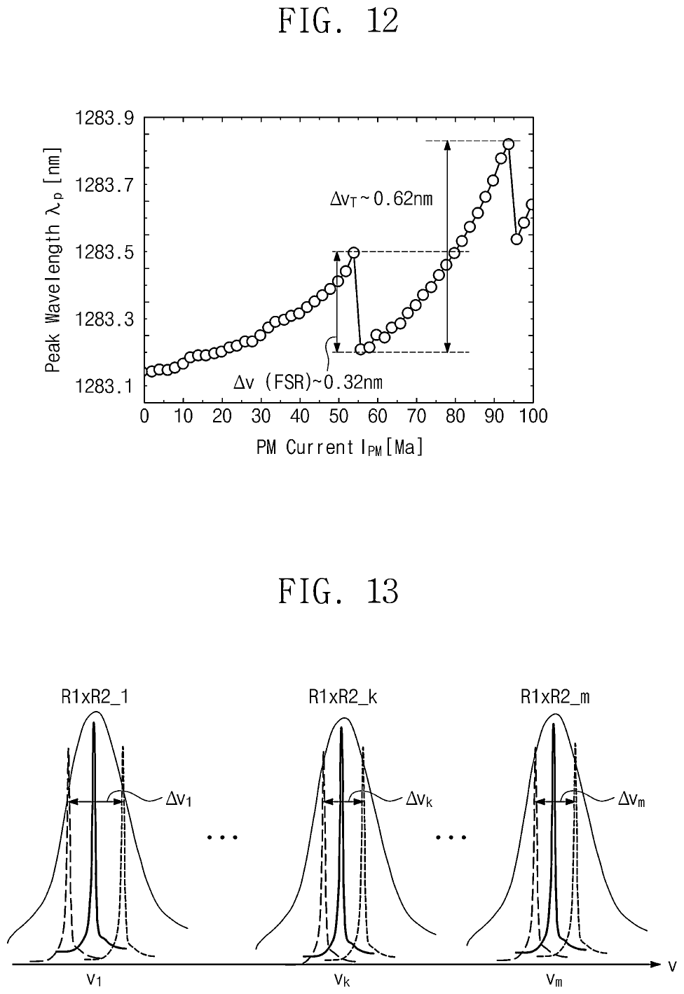

FIG. 12 shows a peak wavelength according to the modulation current provided to the electrodes 50 of the phase modulation region of FIG. 2.

Referring to FIG. 12, when the modulation current changes from about 55 mA to about 90 mA, the peak wavelength may continuously increase within the wavelength variation range of about 0.6 nm from 1283.2 nm to about 1283.8 nm. The frequency-tuning range may be about 116 GHz.

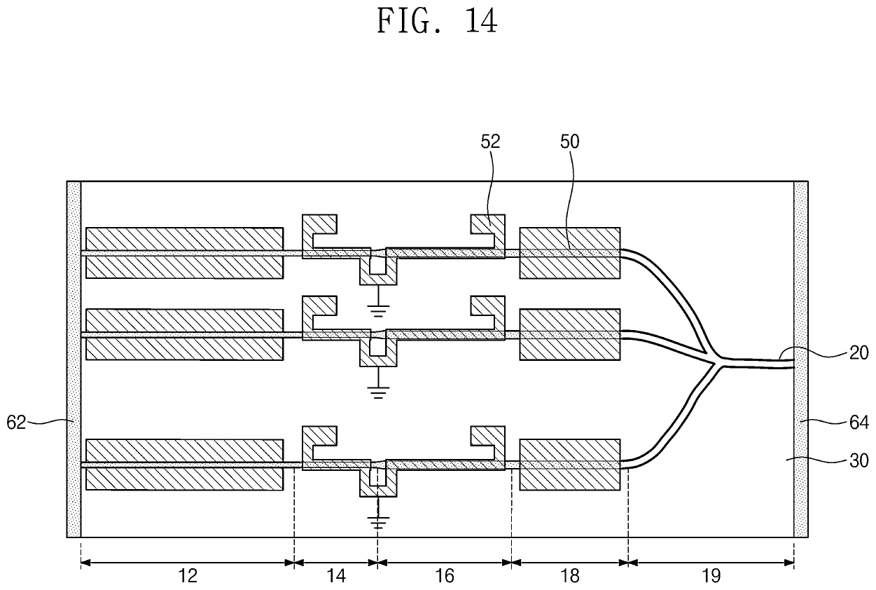

FIG. 13 shows a driving spectrum for each channel of the laser light generated in the continuous frequency-tuning array light sources 100.

Referring to FIG. 13, the continuous frequency-tuning array light sources 100 of the inventive concept may have a resolution enhancement effect as the maximum array number from 1 to m according to the tuning bandwidth increase effect.

FIG. 14 shows an example continuous frequency-tuning array light sources 100 according to the present inventive concept.

Referring to FIG. 14, the electrodes 50 in the phase modulation region 14 and the internal reflection region 16 may be connected. The electrodes 50 may be grounded between the phase modulation region 14 and the internal reflection region 16. The electrodes 50 of the phase modulation region 14 and the internal reflection region 16 may be used as the heat electrodes.

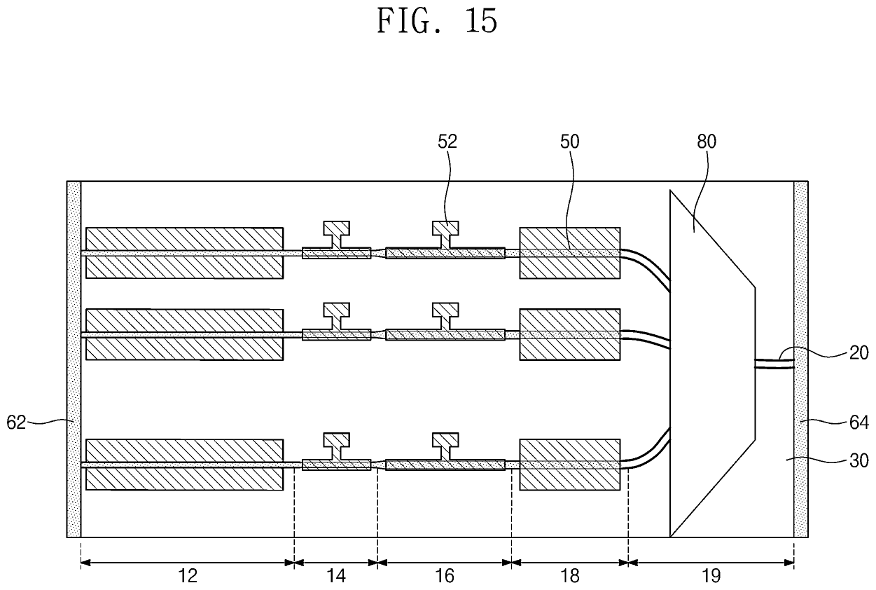

FIG. 15 shows an example continuous frequency-tuning array light sources 100 according to the present inventive concept.

Referring to FIG. 15, the electrodes 50 in the phase modulation region 14 and the internal reflection region 16 may be disconnected. The electrodes 50 of the phase modulation region 14 and the internal reflection region 16 may provide an electric field to the core layer 20.

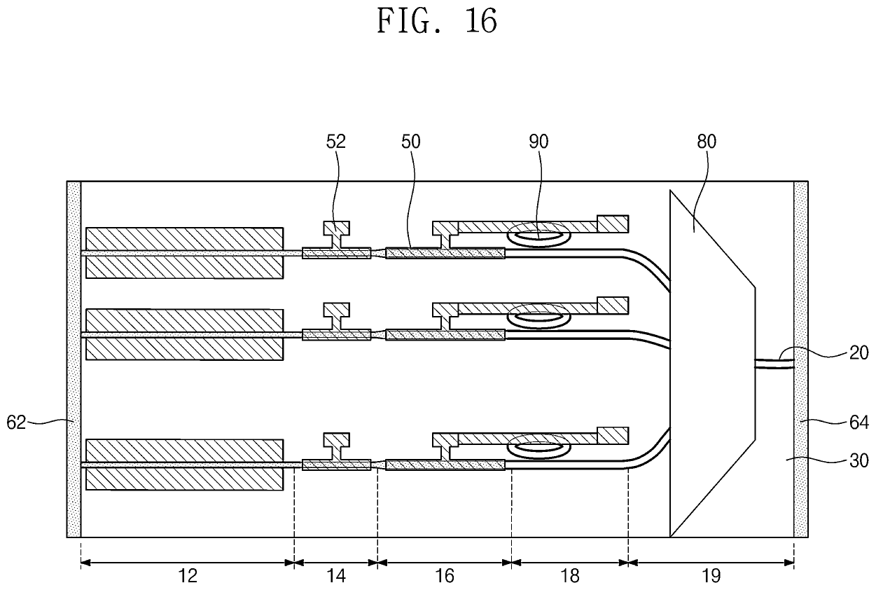

FIG. 16 shows an example continuous frequency-tuning array light sources 100 according to the present inventive concept.

Referring to FIG. 16, each of the continuous frequency-tuning array light sources 100 of the inventive concept may further include a resonant ring 90 in the amplification region 18. The resonant ring 90 may be adjacent to the core layer 20 in a plan view. The resonant ring 90 may amplify the laser light.

According to the above-described, the continuous frequency-tuning array light source may adopt the core layer and the upper clad layer having different thicknesses in the phase modulation region and the internal reflection region to continuously tune frequencies of laser light without mode hopping and increase the tuning efficiency.

The foregoing description is about detailed examples for practicing the inventive concept. The present disclosure includes not only the above-described embodiments but also simply changed or easily modified embodiments. In addition, the inventive concept may also include technologies obtained by easily modifying and practicing the above-described embodiments.

What is claimed is:

1. A continuous frequency-tuning array light source comprising:
a substrate comprising a gain region, a phase modulation region, and an internal reflection region arranged in a first direction;
a core layer extending in the first direction on the substrate and comprising a grating in the internal reflection region;
an upper clad layer on the core layer and the substrate;
external reflection coating on one side wall of the substrate adjacent to the gain region, the core layer, and the upper clad layer;
a dielectric layer on the upper clad layer in the phase modulation region and the internal reflection region;
an ohmic contact layer on the upper clad layer in the gain region; and
electrodes on the dielectric layer and the ohmic contact layer.

2. The continuous frequency-tuning array light source of claim 1, wherein the substrate comprises air holes in the phase modulation region and the internal reflection region.

3. The continuous frequency-tuning array light source of claim 2, wherein the air holes comprise:
first air holes provided in the phase modulation region and having a first thickness; and
second air holes provided in the internal reflection region and having a second thickness smaller than the first thickness.

4. The continuous frequency-tuning array light source of claim 1, wherein the core layer has a third thickness in the gain region and the internal reflection region, and a fourth thickness greater than the third thickness in the phase modulation region.

5. The continuous frequency-tuning array light source of claim 1, wherein the core layer has a first width in the phase modulation region, and a second width greater than the first width in the internal reflection region.

6. The continuous frequency-tuning array light source of claim 1, wherein the upper clad layer has a fifth thickness in the gain region and a sixth thickness smaller than the fifth thickness in the phase modulation region.

7. The continuous frequency-tuning array light source of claim 6, wherein the upper clad layer has a seventh thickness smaller than the fifth thickness and greater than the sixth thickness in the internal reflection region.

8. The continuous frequency-tuning array light source of claim 1, wherein the gain region has a first length and the phase modulation region has a second length smaller than the first length.

9. The continuous frequency-tuning array light source of claim 1, further comprising:
a bottom electrode provided under the substrate.

10. The continuous frequency-tuning array light source of claim 1, wherein the core layer comprises a quantum well layer in the gain region.

11. A continuous frequency-tuning array light source comprising:
a substrate having a gain region, a phase modulation region, an internal reflection region, an amplification region, and a coupling region arranged in a first direction and having air holes in the phase modulation region and the internal reflection region;
a core layer provided on the substrate, extending from the gain region to the coupling region, having a grating in the internal reflection region, and being selectively thick in the phase modulation region;
an upper clad layer disposed on the core layer and the substrate, and being selectively thin in the phase modulation region;
external reflection coating on one side wall of the substrate, the core layer, and the upper clad layer of the gain region;
anti-reflection coating disposed on another side wall of the substrate, the core layer, and the upper clad layer;
a dielectric layer on the upper clad layer in the phase modulation region and the internal reflection region;
an ohmic contact layer on the upper clad layer in the gain region; and
electrodes on the dielectric layer and the ohmic contact layer.

12. The continuous frequency-tuning array light source of claim 11, wherein the air holes comprise:
first air holes provided in the phase modulation region and having a first thickness; and
second air holes provided in the internal reflection region and having a second thickness smaller than the first thickness.

13. The continuous frequency-tuning array light source of claim 11, wherein the core layer has a third thickness in the gain region and the internal reflection region, and a fourth thickness greater than the third thickness in the phase modulation region.

14. The continuous frequency-tuning array light source of claim 11, wherein the core layer has a first width in the phase modulation region, and a second width greater than the first width in the internal reflection region.

15. The continuous frequency-tuning array light source of claim 1, wherein
the upper clad layer has a fifth thickness in the gain region and a sixth thickness smaller than the fifth thickness in the phase modulation region, and
the upper clad layer has a seventh thickness smaller than the fifth thickness and greater than the sixth thickness in the internal reflection region.
